(19) United States
(12) Patent Application Publication
(10) Pub. No.: US 2024/0260307 A1
(43) Pub. Date: Aug. 1, 2024

(54) DISPLAY DEVICE

(71) Applicant: Japan Display Inc., Tokyo (JP)

(72) Inventor: Hayata AOKI, Tokyo (JP)

(73) Assignee: Japan Display Inc., Tokyo (JP)

(21) Appl. No.: 18/420,786

(22) Filed: Jan. 24, 2024

(30) Foreign Application Priority Data
Jan. 27, 2023 (JP) 2023-011200

(51) Int. Cl. H10K 50/858; H10K 50/155; H10K 50/17; H10K 50/818; H10K 102/00

(52) U.S. Cl. CPC H10K 50/858; H10K 50/155; H10K 50/17; H10K 50/818; H10K 2102/351

(57) ABSTRACT

A display device includes a substrate, and a plurality of light-emitting elements each composed of a pixel electrode, a lower buffer layer, a light-emitting layer, an upper buffer layer, and a counter electrode stacked in order on the substrate. The lower buffer layer comprises a first hole transport layer, a second hole transport layer, and a third hole transport layer stacked in order on the pixel electrode, and refractive index of the second hole transport layer is higher than refractive index of the first hole transport layer and refractive index of the third hole transport layer.

### CROSS-REFERENCE TO RELATED APPLICATION

This application claims the benefit of priority from Japanese Patent Application No. 2023-011200 filed on Jan. 27, 2023, the entire contents of which are incorporated herein by reference.

### BACKGROUND

### 1. Technical Field

The present disclosure relates to a display device.

### 2. Description of the Related Art

Japanese Patent Application Laid-open Publication No. 2019-40990 and Japanese Patent Application Laid-open Publication No. 2004-247106 describe a plurality of organic EL elements. Organic EL elements are composed of a light-emitting layer and buffer layers, such as a hole transport layer and an electron transport layer, stacked between an anode and a cathode.

Display devices with organic EL elements are required to improve the luminous efficiency of the organic EL elements.

### SUMMARY

A display device according to an embodiment of the present disclosure includes a substrate, and a plurality of light-emitting elements each composed of a pixel electrode, a lower buffer layer, a light-emitting layer, an upper buffer layer, and a counter electrode stacked in order on the substrate. The lower buffer layer comprises a first hole transport layer, a second hole transport layer, and a third hole transport layer stacked in order on the pixel electrode, and refractive index of the second hole transport layer is higher than refractive index of the first hole transport layer and refractive index of the third hole transport layer.

### BRIEF DESCRIPTION OF THE DRAWINGS

FIG. 1 is a plan view schematically illustrating a display device according to an embodiment;

FIG. 2 is a plan view of the configuration of a pixel electrode, a counter electrode, and a bank in a pixel according to the embodiment;

FIG. 3 is a sectional view along line III-III′ of FIG. 2;

FIG. 4 is a sectional view schematically illustrating one light-emitting element in FIG. 3;

FIG. 5 is a graph of the relation between BI and chromaticity of the light-emitting element according to examples and a comparative example;

FIG. 6 is a table indicating the refractive index of a first hole transport layer, a second hole transport layer, and a third hole transport layer of the light-emitting element according to the examples; and

FIG. 7 is a sectional view schematically illustrating the light-emitting element according to a modification.

### DETAILED DESCRIPTION

Exemplary aspects (embodiments) to embody the present disclosure are described below in greater detail with reference to the accompanying drawings. The contents described in the embodiments below are not intended to limit the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present disclosure and easily conceivable by those skilled in the art naturally fall within the scope of the present disclosure. To simplify the explanation, the drawings may possibly illustrate the width, the thickness, the shape, and other elements of each unit more schematically than the actual aspect. These elements, however, are given by way of example only and are not intended to limit interpretation of the present disclosure. In the present disclosure and the figures, components similar to those previously described with reference to previous figures are denoted by like reference numerals, and detailed explanation thereof may be appropriately omitted.

When the term “on” is used to describe an aspect where a first structure is disposed on a second structure in the present specification and the claims, it includes both of the following cases unless otherwise noted: a case where the first structure is disposed directly on and in contact with the second structure, and a case where the first structure is disposed on the second structure with another structure interposed therebetween.

### Embodiments

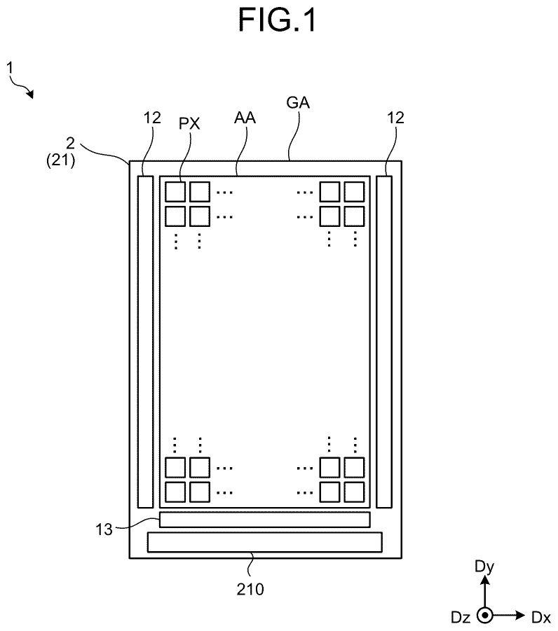

FIG. 1 is a plan view schematically illustrating a display device according to an embodiment. A display device 1 according to the present embodiment is an organic EL display device including organic light-emitting diodes (OLED) serving as self-emitting elements. The display device 1 includes an array substrate 2, pixels PX, a scanning line drive circuit 12, a signal line drive circuit 13, and a drive integrated circuit (IC) 210.

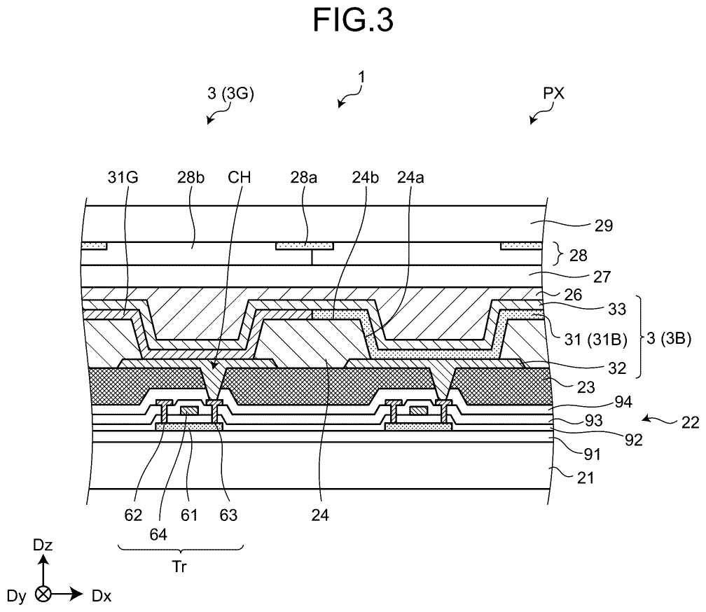

The array substrate 2 is a drive circuit substrate for driving the pixels PX and is also called a backplane or an active matrix substrate. The array substrate 2 is formed using a substrate 21 as a base and includes a plurality of transistors Tr (refer to FIG. 3), a plurality of capacitances, various kinds of wiring, and other components on the substrate 21. A wiring substrate (e.g., flexible printed circuits (FPC)) or the like, which is not specifically illustrated, may be coupled onto the array substrate 2 to receive various control signals and electric power from an external control substrate.

In the following description, a first direction Dx is one direction in a plane parallel to the substrate 21. A second direction Dy is one direction in the plane parallel to the substrate 21 and is orthogonal to the first direction Dx. The second direction Dy may intersect the first direction Dx without being orthogonal thereto. A third direction Dz is a direction orthogonal to the first direction Dx and the second direction Dy and is normal to the substrate 21. The term “plan view” refers to the positional relation when viewed from the third direction Dz.

The scanning line drive circuit 12 is a drive circuit that supplies signals to scanning lines (not illustrated) in a display region AA to drive the pixels PX. The signal line drive circuit 13 is a drive circuit that supplies pixel signals to signal lines (not illustrated) in the display region AA to drive the pixels PX. The drive IC 210 is a circuit that supplies control signals to the scanning line drive circuit 12 and the signal line drive circuit 13 to control display on the pixels PX. At least part of the scanning line drive circuit 12 and the signal line drive circuit 13 may be formed integrally with the drive IC 210. The drive IC 210 is provided on the array substrate 2. The configuration is not limited thereto, and the drive IC 210 may be provided to a wiring substrate coupled to the array substrate 2.

The array substrate 2 has a display region AA and a peripheral region GA. The display region AA is provided with a plurality of pixels PX. The pixels PX are arrayed in a matrix (row-column configuration) in the display region AA. The peripheral region GA is a region outside the display region AA and is not provided with the pixels PX. The peripheral region GA is provided with the scanning line drive circuit 12, the signal line drive circuit 13, and the drive IC 210. The scanning line drive circuit 12 is provided in regions extending along the second direction Dy in the peripheral region GA. The signal line drive circuit 13 and the drive IC 210 are provided in a region extending along the first direction Dx in the peripheral region GA.

To simplify the explanation, the display region AA according to the present embodiment has a rectangular shape, and the peripheral region GA has a rectangular frame shape surrounding the display region AA. The configuration is not limited thereto, and the display region AA may have a polygonal shape or an irregular shape having cutouts (notches) or curved portions in part of the outer periphery. The peripheral region GA can have various shapes depending on the shape of the display region AA.

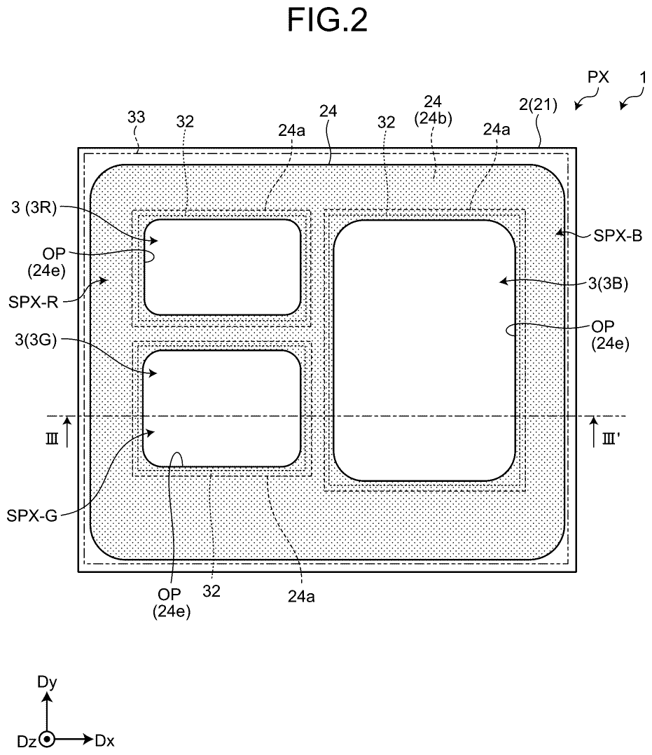

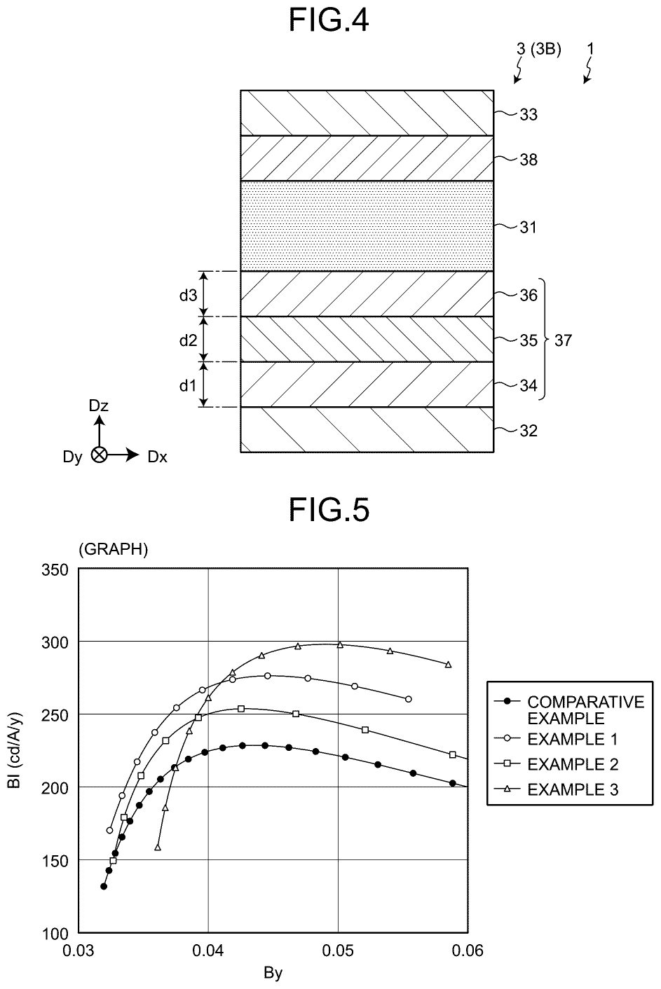

FIG. 2 is a plan view of the configuration of a pixel electrode, a counter electrode, and a bank in the pixel according to the embodiment. FIG. 2 schematically illustrates the configuration of the pixel PX without a light-emitting layer 31, a lower buffer layer 37, an upper buffer layer 38, or other components (refer to FIGS. 3 and 4).

As illustrated in FIG. 2, the pixel PX includes sub-pixels SPX-R, SPX-G, and SPX-B. The sub-pixels SPX-R, SPX-G, and SPX-B each include an organic light-emitting diode as a light-emitting element 3 (refer to FIG. 3). In the following description, the sub-pixels SPX-R, SPX-G, and SPX-B are simply referred to as sub-pixels SPX when they need not be distinguished from one another.

The sub-pixel SPX-R displays red (R), for example. The sub-pixel SPX-G displays green (G), for example. The sub-pixel SPX-B displays blue (B), for example. The sub-pixel SPX-R and the sub-pixel SPX-G are disposed side by side in the second direction Dy. One sub-pixel SPX-B is disposed side by side in the first direction Dx with the sub-pixels SPX-R and SPX-G disposed side by side in the second direction Dy. The configuration is not limited thereto, and the pixel PX may have other arrangements. For example, the sub-pixels SPX-R, SPX-G, and SPX-B may be adjacently disposed in the first direction Dx. Alternatively, the pixel PX may be configured in what is called a PenTile array. The pixel PX is not necessarily composed of three sub-pixels SPX and may be composed of four or more sub-pixels SPX.

As illustrated in FIG. 2, the display device 1 includes the substrate 21, the light-emitting elements 3 (light-emitting elements 3R, 3G, and 3B), and a bank 24. The light-emitting elements 3 each include a light-emitting layer 31, a lower buffer layer 37 and an upper buffer layer 38 (refer to FIGS. 3 and 4), a pixel electrode 32, and a counter electrode 33.

A plurality of pixel electrodes 32 are provided to the respective sub-pixels SPX in a manner separated from one another. More specifically, the pixel electrode 32 of the sub-pixel SPX-R and the pixel electrode 32 of the sub-pixel SPX-G are disposed side by side in the second direction Dy with a space interposed therebetween. The pixel electrode 32 of the sub-pixel SPX-B is disposed side by side with the pixel electrodes 32 of the sub-pixel SPX-R and the sub-pixel SPX-G in the first direction Dx with a space interposed therebetween.

The bank 24 is provided surrounding a plurality of pixel electrodes 32 in plan view. The bank 24 is formed in a protruding shape having an inclined portion 24a and a flat portion 24b. The inclined portion 24a of the bank 24 is provided overlapping the outer periphery of the pixel electrode 32. The flat portion 24b of the bank 24 is provided between the pixel electrodes 32. In other words, the bank 24 has openings OP in the regions overlapping the respective centers of the pixel electrodes 32. An inner wall 24e constituting the opening OP of the bank 24 overlaps the outer periphery of the pixel electrode 32. Light from the light-emitting elements 3R, 3B, and 3G is output to the outside through the openings OP.

The counter electrode 33 is continuously provided over the light-emitting elements 3R, 3G, and 3B (sub-pixels SPX). In other words, the counter electrode 33 is continuously provided covering the pixel electrodes 32 and the bank 24.

The following describes a sectional configuration of the display device 1. FIG. 3 is a sectional view along line III-III′ of FIG. 2. FIG. 3 illustrates the sectional configuration of the sub-pixel SPX-B and the sub-pixel SPX-G. The sectional configuration of the sub-pixel SPX-R is the same as that of the sub-pixels SPX-B and SPX-G, and the description of the sub-pixels SPX-B and SPX-G is also applicable to the sub-pixel SPX-R.

In the following description, the direction from the substrate 21 toward a counter substrate 29 in the direction perpendicular to the surface of the substrate 21 (third direction Dz) is referred to as an “upper side” or simply as “top”. The direction from the counter substrate 29 toward the substrate 21 is referred to as a “lower side” or simply as “bottom”.

As illustrated in FIG. 3, the display device 1 further includes a circuit formation layer 22, a planarization film 23, a sealing film 26, an adhesive layer 27, a filter layer 28, and the counter substrate 29 provided on the substrate 21.

The substrate 21 is an insulating substrate and is a glass substrate made of quartz or alkali-free glass or a resin substrate made of polyimide, for example. If a flexible resin substrate is used as the substrate 21, the display device 1 can be configured as a sheet display. The material of the substrate 21 is not limited to polyimide and may be other resin materials.

The circuit formation layer 22 is a layer provided on the substrate 21 and provided with transistors Tr and various kinds of wiring (not illustrated) for driving the light-emitting elements 3. The transistor Tr in the circuit formation layer 22 is provided in a region overlapping the pixel electrode 32 of the light-emitting element 3. The transistor Tr includes a semiconductor layer 61, a source electrode 62, a drain electrode 63, and a gate electrode 64. The circuit formation layer 22 includes an undercoat film 91, a gate insulating film 92, an interlayer insulating film 93, and a superimposed insulating film 94 as insulating films.

The undercoat film 91 is provided on the substrate 21. The undercoat film 91 is made of an inorganic insulating film, such as a silicon nitride film and a silicon oxide film. The configuration of the undercoat film 91 is not limited to that illustrated in FIG. 3. For example, the undercoat film 91 may be a multilayered film composed of two or three or more layers.

The transistor Tr is provided on the substrate 21. The semiconductor layer 61 is provided on the undercoat film 91. The gate insulating film 92 is provided on the undercoat film 91 to cover the semiconductor layer 61. The gate insulating film 92 is an inorganic insulating film, such as a silicon oxide film. The gate electrode 64 is provided on the gate insulating film 92.

In the example illustrated in FIG. 3, the transistor Tr has a top-gate structure. The configuration is not limited thereto, and the transistor Tr may have a bottom-gate structure or a dual-gate structure in which the gate electrodes 64 are provided on both the upper side and the lower side of the semiconductor layer 61.

The interlayer insulating film 93 is provided on the gate insulating film 92 to cover the gate electrode 64. The interlayer insulating film 93 has a multilayered structure of a silicon nitride film and a silicon oxide film, for example. The source electrode 62 and the drain electrode 63 are provided on the interlayer insulating film 93. The source electrode 62 is coupled to the source region of the semiconductor layer 61 through a contact hole formed in the gate insulating film 92 and the interlayer insulating film 93. The drain electrode 63 is coupled to the drain region of the semiconductor layer 61 through a contact hole formed in the gate insulating film 92 and the interlayer insulating film 93. The superimposed insulating film 94 is provided on the interlayer insulating film 93 to cover the source electrode 62 and the drain electrode 63.

The planarization film 23 is provided on the superimposed insulating film 94 of the circuit formation layer 22 to cover the transistors Tr and various kinds of wiring in the circuit formation layer 22. The planarization film 23 is made of organic insulating material, such as photosensitive acrylic.

The bank 24 is provided on the planarization film 23 on the upper side of the substrate 21. The bank 24 has a protruding shape with the inclined portion 24a and the flat portion 24b. The bank 24 is made of organic insulating material.

FIG. 4 is an enlarged sectional view of one light-emitting element in FIG. 3. As illustrated in FIGS. 3 and 4, the light-emitting element 3 includes the pixel electrode 32, the lower buffer layer 37, the light-emitting layer 31, the upper buffer layer 38, and the counter electrode 33. In the light-emitting element 3, the lower buffer layer 37, the light-emitting layer 31, the upper buffer layer 38, and the counter electrode 33 are stacked in this order on the pixel electrode 32. To simplify the drawing, FIG. 3 does not illustrate the lower buffer layer 37 or the upper buffer layer 38.

The light-emitting element 3 (the pixel electrode 32, the lower buffer layer 37, the light-emitting layer 31, the upper buffer layer 38, and the counter electrode 33) according to the present embodiment is configured as a top emission light-emitting element. In other words, light generated in the light-emitting layer 31 is transmitted through the counter electrode 33 and is output upward (toward the counter substrate 29). The pixel electrode 32 is configured as a reflective electrode. Part of the light generated in the light-emitting layer 31 is transmitted through the lower buffer layer 37, travels toward the pixel electrode 32, and is reflected upward (toward the counter substrate 29) by the pixel electrode 32.

The pixel electrode 32 is provided on the planarization film 23. The pixel electrode 32 is coupled to the drain electrode 63 of the transistor Tr through a contact hole CH (refer to FIG. 3) passing through the planarization film 23. The pixel electrode 32 is the anode of the light-emitting element 3 and is made of metal material. Alternatively, the pixel electrode 32 may have a multilayered structure composed of translucent conductive material, such as indium tin oxide (ITO), and light-reflective metal material, for example.

As described above, the bank 24 has the openings in the regions overlapping the respective centers of the pixel electrodes 32. The lower buffer layer 37, the upper buffer layer 38, and the counter electrode 33 (neither the lower buffer layer 37 nor the upper buffer layer 38 is illustrated in FIG. 3) are continuously provided covering the pixel electrodes 32 and the bank 24.

As illustrated in FIG. 4, the lower buffer layer 37 includes a first hole transport layer 34, a second hole transport layer 35, and a third hole transport layer 36. In the lower buffer layer 37, the first hole transport layer 34, the second hole transport layer 35, and the third hole transport layer 36 are stacked in this order on the pixel electrode 32.

The first hole transport layer 34, the second hole transport layer 35, and the third hole transport layer 36 transport holes from the pixel electrode 32 (anode) to the light-emitting layer 31. The first hole transport layer 34, the second hole transport layer 35, and the third hole transport layer 36 are made of organic material with higher hole mobility than the upper buffer layer 38.

The light-emitting layer 31 is formed by an organic electroluminescent (EL) layer. The light-emitting layer 31 is provided on the lower buffer layer 37 over the region overlapping the pixel electrode 32 and the region overlapping the bank 24. The light-emitting layer 31 is selectively formed for each sub-pixel SPX.

The upper buffer layer 38 is provided on the light-emitting layer 31 over the region overlapping the pixel electrode 32 and the region overlapping the bank 24. The upper buffer layer 38 is an electron transport layer. The upper buffer layer 38 is not limited to a single layer and may have a multilayered structure composed of two or three or more layers including an electron injection layer or the like.

The counter electrode 33 is provided on the upper buffer layer 38. The counter electrode 33 is provided over the display region AA (refer to FIG. 1) to cover the light-emitting layers 31 of the sub-pixels SPX. The counter electrode 33 needs to be translucent because the display device 1 according to the present embodiment has the top emission structure. The counter electrode 33 is made of a transflective metal film (e.g., MgAg) and is formed as such a thin film that the light output from the light-emitting layer 31 can be transmitted therethrough. The pixel electrode 32 according to the present embodiment serves as the anode, and the counter electrode 33 serves as the cathode. The counter electrode 33 is not limited to a transflective metal film and may be made of translucent conductive material, such as ITO.

The counter electrode 33 is formed over the display region AA and a cathode contact portion (not illustrated) provided near the display region AA and is coupled to the conductive layer of the circuit formation layer 22 at the cathode contact portion.

Referring back to FIG. 3, the sealing film 26 is provided on the counter electrode 33 to cover the light-emitting elements 3. The sealing film 26 is an inorganic film, such as a silicon nitride film and an aluminum oxide film, or a resin film, such as an acrylic film. The sealing film 26 is not limited to a single layer and may be a multilayered film composed of two or more layers combining the inorganic film and the resin film described above. The sealing film 26 satisfactorily seals the light-emitting elements 3 and can prevent moisture from entering from the upper surface.

The filter layer 28 is bonded to the sealing film 26 by the adhesive layer 27. The filter layer 28 includes a light-shielding layer 28a and color filters 28b. The light-shielding layer 28a is provided between the adjacent sub-pixels SPX. The color filters 28b are colored in different colors for the respective sub-pixels SPX. The color filters 28b are provided overlapping the respective light-emitting elements 3. The color filters 28b each include a color layer colored in the same color as that of the light output from the corresponding light-emitting element 3. In the adjacent light-emitting elements 3B and 3G (sub-pixels SPX-G and SPX-B), the periphery of the color filter 28b overlapping the light-emitting element 3B is in contact with the periphery of the color filter 28b overlapping the light-emitting element 3G in the first direction Dx. The configuration is not limited thereto, and the peripheries of the adjacent color filters 28b may overlap in the third direction Dz.

The light-shielding layer 28a is provided between the adjacent sub-pixels SPX and is stacked between the color filters 28b and the counter substrate 29 in the third direction Dz. The light-shielding layer 28a is also called a black matrix. More specifically, the light-shielding layer 28a is provided overlapping the boundary between the adjacent color filters 28b. The light-shielding layer 28a is provided in the region overlapping the flat portion 24b of the bank 24 and has openings in the regions overlapping part of the bank 24 (inclined portion 24a) and the pixel electrodes 32.

The counter substrate 29 is provided covering the filter layer 28. The counter substrate 29 is a cover panel made of a glass or resin substrate.

The following describes the lower buffer layer 37 illustrated in FIG. 4 in greater detail. The refractive index of the second hole transport layer 35 according to the present embodiment is higher than that of the first hole transport layer 34 and that of the third hole transport layer 36. The second hole transport layer 35 is a high refractive index layer made of organic material with a high refractive index, and the first hole transport layer 34 and the third hole transport layer 36 are low refractive index layers made of organic material with a lower refractive index than the second hole transport layer 35. In other words, the lower buffer layer 37 is composed of a low refractive index layer (first hole transport layer 34), a high refractive index layer (second hole transport layer 35), and a low refractive index layer (third hole transport layer 36) stacked in this order on the pixel electrode 32.

The refractive index of the first hole transport layer 34 may be equal to or different from that of the third hole transport layer 36. The first hole transport layer 34 according to the present embodiment is made of organic material with a p-type dopant added and serves as both a hole injection layer and a hole transport layer. The hole injection layer is made of material with high injection efficiency of holes from the pixel electrode 32 (anode). The amount of the added p-type dopant is approximately 0.1 wt % to 0.5 wt % of the organic material of the first hole transport layer 34 excluding the p-type dopant, for example. The third hole transport layer 36 is made of organic material with no p-type dopant added.

When the emission wavelength of the light-emitting layer 31 is λ, the total thickness of the lower buffer layer 37 is 3λ/4. Each of the thickness d1 of the first hole transport layer 34, the thickness d2 of the second hole transport layer 35, and the thickness d3 of the third hole transport layer 36 is λ/4. The thickness d1 of the first hole transport layer 34 serving as both the hole injection layer and the hole transport layer is substantially equal to the thickness d2 of the second hole transport layer 35 and the thickness d3 of the third hole transport layer 36.

With this configuration, light traveling toward the pixel electrode 32 out of the light (emission wavelength λ) output from the light-emitting layer 31 travels to the pixel electrode 32 while repeatedly being reflected and transmitted between the first hole transport layer 34, the second hole transport layer 35, and the third hole transport layer 36, and is reflected by the pixel electrode 32. The refractive indices and the thicknesses of the first hole transport layer 34, the second hole transport layer 35, and the third hole transport layer 36 have the relation described above. Therefore, beams of the light reflected between the layers intensify each other and travel toward the counter electrode 33.

Specifically, the light reflected at the interface between the pixel electrode 32 and the first hole transport layer 34 and the light reflected at the interface between the first hole transport layer 34 and the second hole transport layer 35 intensify each other. The light reflected at the interface between the first hole transport layer 34 and the second hole transport layer 35 and the light reflected at the interface between the second hole transport layer 35 and the third hole transport layer 36 intensify each other. The light reflected at the interface between the second hole transport layer 35 and the third hole transport layer 36 and the light reflected at the interface between the third hole transport layer 36 and the light-emitting layer 31 intensify each other.

Therefore, the display device 1 according to the present embodiment can improve the extraction efficiency of light from the light-emitting element 3 at a predetermined emission wavelength λ. As a result, the display device 1 according to the present embodiment can improve the substantial luminous efficiency. The first hole transport layer 34, the second hole transport layer 35, and the third hole transport layer 36 are configured to intensify the light at the emission wavelength λ, thereby enhancing the color purity.

The thicknesses of the first hole transport layer 34, the second hole transport layer 35, and the third hole transport layer 36 differ depending on the emission wavelength λ of the light-emitting elements 3R, 3G, and 3B. As described above, the first hole transport layer 34 according to the present embodiment serves as both the hole injection layer and the hole transport layer. This configuration can reduce the number of layers the thickness of which needs to be changed depending on the light-emitting elements 3R, 3G, and 3B compared with a case where a hole injection layer 39 (refer to FIG. 7) is additionally formed separately from the first hole transport layer 34, the second hole transport layer 35, and the third hole transport layer 36. Therefore, the production load can be reduced.

The first hole transport layer 34, the second hole transport layer 35, and the third hole transport layer 36 are formed by vapor deposition. More specifically, the organic material of the first hole transport layer 34 and the p-type dopant are deposited by co-evaporation. This method can reduce variations in thickness between the first hole transport layer 34, the second hole transport layer 35, and the third hole transport layer 36 compared with a case where they are deposited by sputtering, for example. As a result, the display device 1 can suppress variations in optical characteristics (chromaticity and luminous efficiency).

### Examples

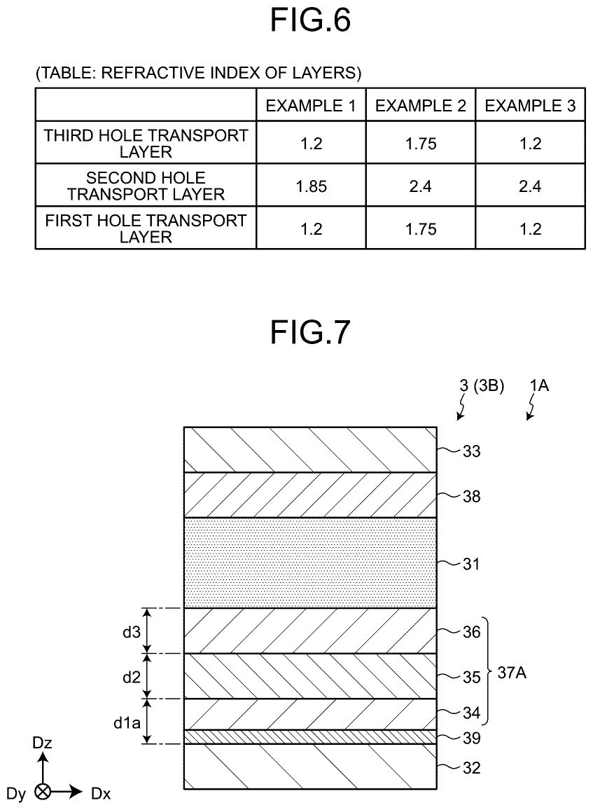

FIG. 5 is a graph of the relation between BI and chromaticity of the light-emitting element according to examples and a comparative example. FIG. 6 is a table indicating the refractive index of the first hole transport layer, the second hole transport layer, and the third hole transport layer of the light-emitting element according to the examples. In the graph in FIG. 5, the horizontal axis indicates chromaticity coordinate y in the CIExy chromaticity diagram, and the vertical axis indicates blue index (hereinafter referred to as BI). BI (=current efficiency (cd/A)/chromaticity (CIE-y)) is one of the indicators of blue light emission characteristics. Blue light emission tends to have higher color purity as CIE-y is smaller, and blue light emission with high color purity can express a wide range of blue colors at low luminance. The use of blue light emission with high color purity reduces the luminance required to express blue, resulting in lower power consumption. Therefore, the light-emitting element 3 with higher BI has higher efficiency as a blue light-emitting device used in displays.

Examples 1, 2, and 3 illustrated in FIG. 5 indicate simulation results of BI of the light-emitting element 3 when the refractive indices of the first hole transport layer 34, the second hole transport layer 35, and the third hole transport layer 36 are different. The light-emitting element according to a comparative example illustrated in FIG. 5 is a light-emitting element including a single-layered low refractive index layer (a refractive index of 1.2 to 1.75 and a thickness of 3λ/4) as the hole transport layer.

As indicated in the table in FIG. 6, the refractive index of the second hole transport layer 35 is higher than that of the first hole transport layer 34 and that of the third hole transport layer 36 in all of Examples 1, 2, and 3. Specifically, in Example 1, the refractive index of the first hole transport layer 34 and the third hole transport layer 36 is 1.2, and the refractive index of the second hole transport layer 35 is 1.85. In Example 2, the refractive index of the first hole transport layer 34 and the third hole transport layer 36 is 1.75, and the refractive index of the second hole transport layer 35 is 2.4. In Example 3, the refractive index of the first hole transport layer 34 and the third hole transport layer 36 is 1.2, and the refractive index of the second hole transport layer 35 is 2.4.

In all of Examples 1, 2, and 3, each of the thickness d1 of the first hole transport layer 34, the thickness d2 of the second hole transport layer 35, and the thickness d3 of the third hole transport layer 36 is λ/4 (λ=460 nm).

As illustrated in FIG. 5, the light-emitting elements according to Examples 1 and 2 have higher BI than the comparative example in the range of chromaticity in the graph. The light-emitting element according to Example 3 also has higher BI than the comparative example at least in the range of chromaticity of 0.038 or higher. When compared in terms of maximum BI, the maximum BI is larger in the order of the comparative example, Example 2, Example 1, and Example 3.

These results indicate that the light extraction efficiency of the light-emitting element 3 can be improved by making the refractive index of the second hole transport layer 35 higher than that of the first hole transport layer 34 and that of the third hole transport layer 36. More preferably, the refractive index of the first hole transport layer 34 and the third hole transport layer 36 is 1.2 to 1.75. The refractive index of the second hole transport layer 35 is 1.85 to 2.4. Within these ranges of the refractive index, the light extraction efficiency can be more effectively improved.

### Modifications

FIG. 7 is a sectional view schematically illustrating the light-emitting element according to a modification. In the following description, the same components as those described in the embodiment above are denoted by like reference numerals, and duplicate explanation thereof is omitted.

As illustrated in FIG. 7, a display device 1A according to the modification is different from the embodiment described above in that it includes a hole injection layer 39. The hole injection layer 39 is provided between the pixel electrode 32 and the first hole transport layer 34 in the third direction Dz. The hole injection layer 39 is made of material with higher injection efficiency of holes from the pixel electrode 32 (anode) than the first hole transport layer 34, the second hole transport layer 35, and the third hole transport layer 36 of a lower buffer layer 37A. The first hole transport layer 34 according to the present modification is made of organic material including no p-type dopant and not serving the function of the hole injection layer 39.

Also in the present modification, the refractive index of the second hole transport layer 35 is higher than that of the first hole transport layer 34 and that of the third hole transport layer 36. In other words, the first hole transport layer 34 and the third hole transport layer 36 are formed as low refractive index layers, and the second hole transport layer 35 is formed as a high refractive index layer.

The total thickness of the lower buffer layer 37 and the hole injection layer 39 is 3λ/4. In other words, the total thickness d1a of the first hole transport layer 34 and the hole injection layer 39 is λ/4. Each of the thickness d2 of the second hole transport layer 35 and the thickness d3 of the third hole transport layer 36 is λ/4.

The present modification can improve the luminous efficiency of the light-emitting element 3 similarly to the embodiment described above. In the present modification, however, it is necessary to adjust the thicknesses of the first hole transport layer 34, the second hole transport layer 35, the third hole transport layer 36, and the hole injection layer 39 depending on the emission colors (depending on the emission wavelengths λ) of the respective light-emitting elements 3R, 3G, and 3B.

The layers of the lower buffer layer 37 according to the embodiment and the modification described above are hole transport layers, and the upper buffer layer 38 is an electron transport layer. The configuration is not limited thereto, and if the light-emitting element 3 has an inverse multilayered structure, the layers of the lower buffer layer 37 may be electron transport layers, and the upper buffer layer 38 may be a hole transport layer. In this case, the pixel electrode 32 is the cathode, and the counter electrode 33 is the anode.

What is claimed is:

1. A display device comprising:
a substrate; and
a plurality of light-emitting elements each composed of a pixel electrode, a lower buffer layer, a light-emitting layer, an upper buffer layer, and a counter electrode stacked in order on the substrate, wherein
the lower buffer layer comprises a first hole transport layer, a second hole transport layer, and a third hole transport layer stacked in order on the pixel electrode, and
refractive index of the second hole transport layer is higher than refractive index of the first hole transport layer and refractive index of the third hole transport layer.

2. The display device according to claim 1, wherein the first hole transport layer is made of organic material including a p-type dopant and serves as both a hole injection layer and a hole transport layer.

3. The display device according to claim 1, wherein the refractive index of the first hole transport layer and the third hole transport layer is 1.2 to 1.75.

4. The display device according to claim 1, wherein the refractive index of the second hole transport layer is 1.85 to 2.4.

5. The display device according to claim 1, wherein, when an emission wavelength of the light-emitting layer is λ, each of the thicknesses of the first hole transport layer, the second hole transport layer, and the third hole transport layer is λ/4.

6. The display device according to claim 1, further comprising a hole injection layer provided between the pixel electrode and the first hole transport layer in a direction perpendicular to the substrate.

7. The display device according to claim 6, wherein
when an emission wavelength of the light-emitting layer is λ, the total thickness of the hole injection layer and the first hole transport layer is λ/4, and
each of the thicknesses of the second hole transport layer and the third hole transport layer is λ/4.

8. The display device according to claim 1, wherein
the pixel electrode, the lower buffer layer, the light-emitting layer, the upper buffer layer, and the counter electrode constitute the light-emitting element with a top emission structure, and
the pixel electrode is a reflective electrode.
